(19) United States
(12) Patent Application Publication
(10) Pub. No.: US 2010/0039786 A1
(43) Pub. Date: Feb. 18, 2010

(54) COMMUNICATION DEVICE

(75) Inventors: Shuqiang Gong, Shenzhen (CN); Yongquan He, Shenzhen (CN); Qizhi Zhan, Shenzhen (CN); Chaoyan Zhang, Shenzhen (CN); Guifu Xie, Shenzhen (CN); Guzheng Wu, Shenzhen (CN)

Correspondence Address: Huawei Technologies Co., Ltd.;c/o Darby & Darby P.C., P.O. Box 770, Church Street Station, New York, NY, 10008-0770, US

(73) Assignee: SHENZHEN HUAWEI COMMUNICATION TECHNOLOGIES CO., LTD., Shenzhen (CN)

(21) Appl. No.: 12/506,909

(22) Filed: Jul. 21, 2009

(30) Foreign Application Priority Data
Aug. 13, 2008 (CN) 200820132561.7

(51) Int. Cl. H05K 5/02; G06F 13/20

(52) U.S. Cl. 361/814; 710/313

(57) ABSTRACT

A communication device is provided, which has a PCI Express interface and includes: an interface circuit board, configured to bear the PCI Express interface; a main circuit board, connected to the interface circuit board through soft link, and configured to transmit/receive and process data of the PCI Express interface; a guide rail, configured to bear the main circuit board, so that the main circuit board slides between a use position and an accommodation position through the guide rail; and an antenna, installed on the main circuit board, and located at different positions with the movement of the main circuit board. According to an embodiment of this invention, the antenna in the main circuit can be exposed out of a case of the communication device, or accommodated into the case of the communication device, thus being convenient for the storage and transportation of the communication device.

The present application claims priorities of Chinese Patent Applications No. 200820132561.7, titled “COMMUNICATION DEVICE”, filed on Aug. 13, 2008, the whole contents of which are incorporated herein by reference.

### FIELD OF THE TECHNOLOGY

This invention relates to the field of network communication, and more particularly, to a communication device.

### BACKGROUND OF THE INVENTION

With the maturity of electronic device technology and increasing competition in the electronic device market, the requirements of users for electronic device have changed significantly, which not only require the electronic device to have good internal quality and perfect functions and performance, but also require the electronic terminal to be smaller in appearance. Presently, peripheral component interconnection (PCI) Express interface products have been widely used in communication device products. The products are mostly advantageous in small volume, and thus can be directly inserted into the Express port of the portable device for use.

The data card provided with PCI Express interface (hereinafter referred to as Express data card) is a wireless data transmission device, and when the Express data card is being used, the antenna must expose out of the portable device to transmit/receive radio-frequency signals. Presently, in order to accommodate the requirement that the antenna must be exposed, the length of the data card of the Express interface is designed to exceed the Express slot of the portable device for 3-5 cm, and the antenna is placed in the exceeding part. When the portable device is in a use state, it is not important that the antenna is out of the portable device. But, when transporting the portable device, as the antenna part of the data card is exposed out of the portable device, in order not to damage the device, the data card should be removed and stored in another place; otherwise, it might bring unnecessary troubles to the user due to inconvenient storage.

In the conventional technology, a data card having an Express interface is provided. When the data card is inserted into the slot of the portable device, the antenna part exposed out of the portable device is about 4 cm long, and the antenna is non-retractable. As the data card is longer than the slot, when the data card is inserted on the portable device, the antenna part of the data card is definitely exposed out of the portable device. When not being used, the data card should be removed; otherwise, it might cause inconvenience during transportation of the portable device, or even damage the device.

In the conventional technology, another data card for portable device is provided with a folded antenna. When the portable device is not used, the antenna part is partly retracted into the data card. Only when the portable device works, the antenna is extracted out and exposed out of the portable device.

However, as the volume of the antenna is small, it is difficult to make a movable mechanism of the antenna, and the structure of the antenna is complex. Further, the movement of antenna means that the antenna and the circuit board should be connected in a flexible manner, thus significantly impacting the performance of the radio-frequency component, and having certain interferences on the performance of the circuit.

### SUMMARY OF THE INVENTION

This invention is directed to a communication device, in which the storage and transportation of the communication device is convenient due to the retractable structure of the main circuit board.

In order to achieve the above objective, this invention provides a communication device in an embodiment, which has an Express interface and includes: an interface circuit board, a main circuit board, a guide rail, and an antenna.

The interface circuit board is configured to bear the Express interface.

The main circuit board is connected to the interface circuit board through soft link, and configured to transmit/receive and process data of the Express interface.

The guide rail bears the main circuit board, so that the main circuit board slides between a use position and an accommodation position through the guide rail.

The antenna is installed on the main circuit board, and located at different positions with the movement of the main circuit board.

Compared with the conventional technology, this invention has the following advantages. According to an embodiment of this invention, the main circuit board adopts a retractable structure. When the main circuit board moves to the use position, the antenna is just exposed out of the case of the communication device, so that the antenna can transmit/receive radio-frequency signals, thus meeting the use requirements of the antenna. When the main circuit board moves to the accommodation position, the antenna is accommodated into the case of the communication device, thus being convenient for the storage and transportation of the communication device. Further, the communication device has a simple design and can be realized easily, thus being beneficial to improving the automatization of the communication device.

### BRIEF DESCRIPTION OF THE DRAWINGS

In order to make the technical solution of the embodiments of this invention more understandable, drawings used in the description of the embodiments are simply introduced hereinafter. Obviously, the drawings described herein are merely some embodiments of this invention, and those of ordinary skill in the art can get other drawings according to the drawings without any creative labor.

FIG. 1 is a schematic structural view of a communication device having an Express interface according to an embodiment of this invention;

FIG. 2 is a schematic structural view of a communication device having an Express interface according to a first embodiment of this invention;

FIG. 3 is a schematic structural view of a communication device with an antenna in an accommodation state according to the first embodiment of this invention;

FIG. 4 is a schematic structural view of a communication device having an Express interface according to a second embodiment of this invention; and

FIG. 5 is a schematic structural view of a communication device with an antenna in an accommodation state according to the second embodiment of this invention.

### DETAILED DESCRIPTION OF THE EMBODIMENTS

Hereinafter, the technical solution of the embodiments of this invention will be described clearly and completely with reference to the drawings. Definitely, the described embodiments are merely a part of the embodiment of this invention, not all the embodiments. Based on the embodiments of this invention, all other embodiments made by those of ordinary skill in the art without any creative labor are within the protection scope of this invention.

In an embodiment of this invention, a communication device is provided. The communication device has an Express interface. According to the embodiment of this invention, when using a data card, the data card is moved to a use position, and an antenna is just exposed out of a case of the communication device, so that the antenna can transmit/receive radio-frequency signals, thus meeting the use requirements of the antenna. When not using the data card, the data card is moved to an accommodation state, and the antenna is accommodated into the case of the data card, thus being convenient for the storage and transportation of the communication device. The communication device according to the embodiment of this invention has a simple structure and can be realized easily, and is beneficial to improving the automatization of the communication device.

Hereinafter, the implementation of this invention is further described with reference to the following drawings and embodiments in detail.

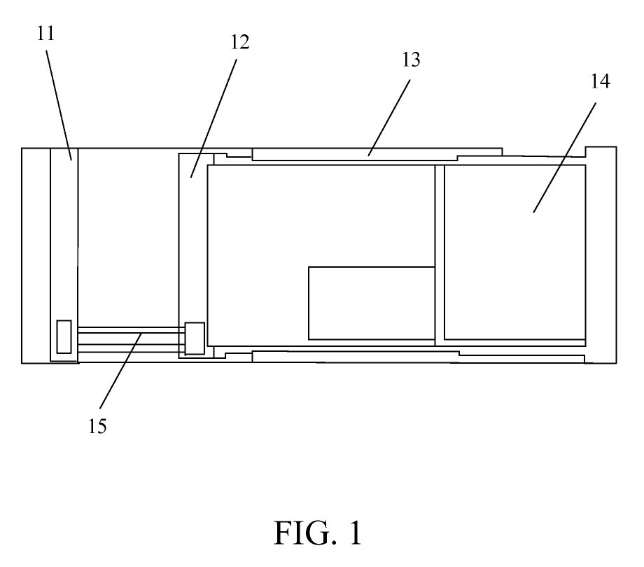

FIG. 1 is a schematic structural view of a communication device according to an embodiment of this invention. As shown in FIG. 1, the communication device includes: an interface circuit board 11, a main circuit board 12, a guide rail 13, and an antenna 14.

The interface circuit board 11 is configured to bear an Express interface.

The main circuit board 12 is connected to the interface circuit board 11 through soft link, and configured to transmit/receive and process data of the Express interface.

The guide rail 13 bears the main circuit board 12, so that the main circuit board 12 slides between a use position and an accommodation position through the guide rail 13.

The antenna 14 is installed on the main circuit board 12, and located at different positions with the movement of the main circuit board 12.

The main circuit board 12 slides through the guide rail 13 and is switched between the use position and the accommodation position, and can be locked at the use position and the accommodation position respectively. The soft link can be realized through a flexible wire, or a soft circuit board, such as a flexible printed circuit board (FPC). The embodiment of this invention is exemplified with the main circuit board 12 and the interface circuit board 11 connected through a flexible wire 15.

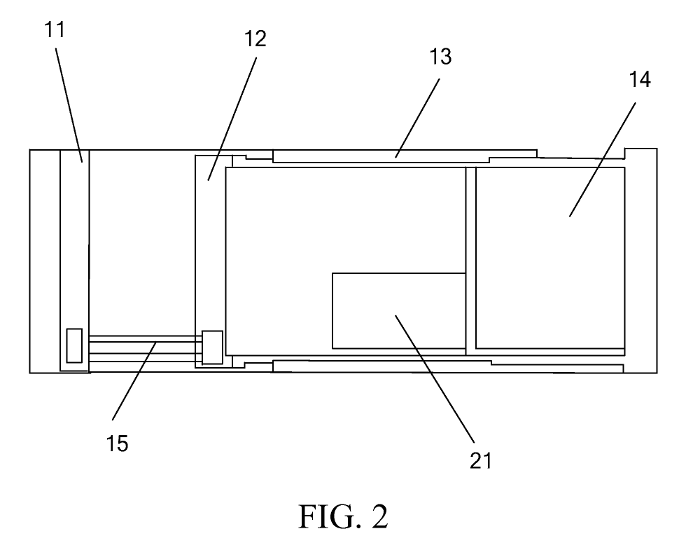

FIG. 2 is a schematic structural view of a communication device in use state according to a first embodiment of this invention.

In this embodiment, the switch of the main circuit board 12 between the use position and the accommodation position is realized in a manual manner.

The communication device includes a main circuit board 12 and an interface circuit board 11. In the embodiment of this invention, the main circuit board 12 is configured to receive data of and supply power to the Express interface, transmit/receive and process radio-frequency signals, and process all other data. The interface circuit board 11 is configured to bear the Express interface and educe corresponding data signal cables, and provide suitable interfaces. The interface circuit board 11 does not perform any data processing. The main circuit board 12 and the interface circuit board 11 are connected through the flexible wire 15.

According to the embodiment of this invention, the main circuit board 12 slides through the guide rail 13 in a manual manner, thus realizing the switching of the main circuit board 12 between the use position and the accommodation position. The main circuit board 12 can be locked at the use position and the accommodation position respectively.

The use position of the main circuit board 12 is corresponding to a use state of the main circuit board 12, and the accommodation position of the main circuit board 12 is corresponding to an accommodation state of the main circuit board 12.

The interface circuit board 11 has an Express interface thereon. When the main circuit board 12 moves to the use position through the guide rail 13, the connection of the main circuit board 12 and the Express interface is maintained, and signals are transmitted to corresponding interfaces of the main circuit board 12 through the flexible wire 15.

The main circuit board 12 is located behind the interface circuit board 11, substantially in the same plain with the interface circuit board 11, and connected to the interface circuit board 11 through the flexible wire 15. Moreover, the main circuit board 12 receives the data of the Express interface, and supplies power to the interface circuit board 11. In addition to a data processing chip and a circuit, the main circuit board 12 further includes an antenna 14, a radio-frequency chip, and a circuit. All the circuits are located on a circuit board, so that the circuit layout is compact with a simple structure.

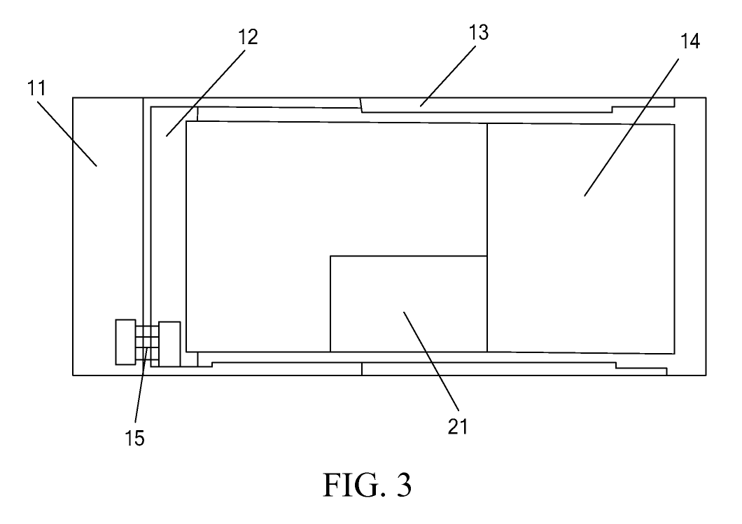

The antenna 14 on the main circuit board 12 is configured to transmit and receive data. The antenna 14 is located at different positions with the movement of the main circuit board 12. The communication device includes a case. When the main circuit board 12 moves to the use position, the antenna 14 is just exposed out of the case of the communication device, and at this time, the antenna 14 can transmit/receive radio-frequency signals, thus meeting the use requirements of the antenna 14. When the main circuit board 12 moves to the accommodation position, the antenna 14 is completely accommodated into the case of the communication device, and is not exposed out of the case of the communication device, thus being convenient for the storage and transportation of the communication device. FIG. 3 is a schematic structural view of a communication device in an accommodation state according to the first embodiment of this invention.

Further, the main circuit board 12 is provided with a subscriber identify module (SIM) socket 21. The SIM socket 21 moves with the main circuit board 12. When the main circuit board 12 is at the accommodation position, a load/unload opening of the SIM socket 21 is accommodated into the communication device with the main circuit board 12, thus forming a good sealing protection on the SIM card and the SIM socket 21. When the main circuit board 12 is at the use position, the load/unload opening of the SIM socket 21 is exposed out, for loading/uploading the SIM card.

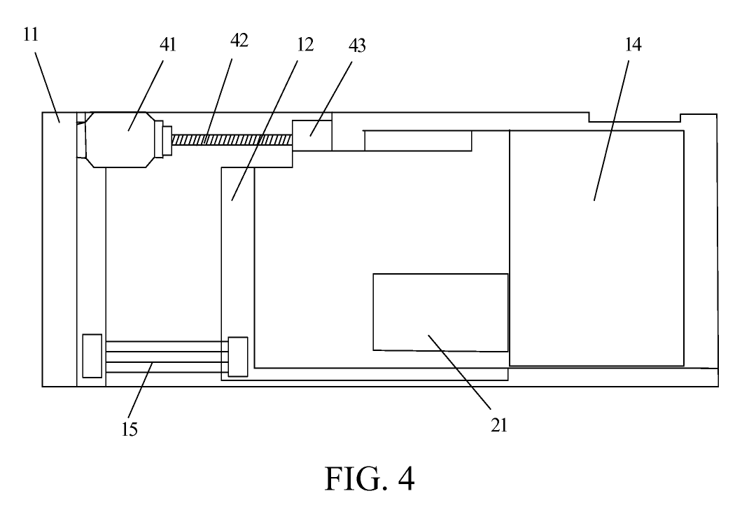

FIG. 4 is a schematic structural view of a communication device in a use state according to a second embodiment of this invention.

In this embodiment, the switching of the main circuit board 12 between the use position and the accommodation position is realized through motor driving.

In this embodiment, the communication device includes a main circuit board 12 and an interface circuit board 11.

The main circuit board 12 is configured to transmit/receive and process data of the Express interface, transmit/receive and process radio-frequency signals, process other data, and realize services.

The interface circuit board 11 is configured to bear the Express interface, educe corresponding data signal cables, and provide suitable interfaces, and may have no data processing function. The main circuit board 12 and the interface circuit board 11 are connected through the flexible wire 15.

The interface circuit board 11 has an Express interface, a drive motor 41 and a drive circuit thereof. The drive current of the drive motor 41 can be directly obtained from the Express interface, thus reducing the loss of current transmission. When the main circuit board 12 is at the use position, the Express interface on the interface circuit board 11 is connected to the main circuit board 12, and the radio-frequency signals are transmitted to the corresponding interface of the main circuit board 12 through the flexible wire 15.

The main circuit board 12 is located behind the interface circuit board 11, and is substantially in the same plane of the interface circuit board 11. In this embodiment, the interface circuit board 11 is provided with a drive motor 41. A screw 42 is disposed between the interface circuit board 11 and the main circuit board 12, an end of the screw 42 is connected to the interface circuit board 11, and the other end of the screw 42 is fixed on the main circuit board 12 through a nut 43. When the drive motor 41 is launched, the drive motor 41 drives the screw 42 to rotate, so as to impel the nut 43 on the screw 42 to move in a parallel manner, thus the nut 43 on the screw 42 drives the main circuit board 12 to move. At the same time, the screw 42 serves as a guide rail and limits the main circuit board 12 to move along the screw 42 in a parallel direction in the length rage of the screw 42. The movement direction of the main circuit board 12 can be changed by changing the rotation direction of the screw 42.

The main circuit board 12 has an antenna 14 configured to transmit and receive data. The antenna 14 is located at different positions with the movement of the main circuit board 12.

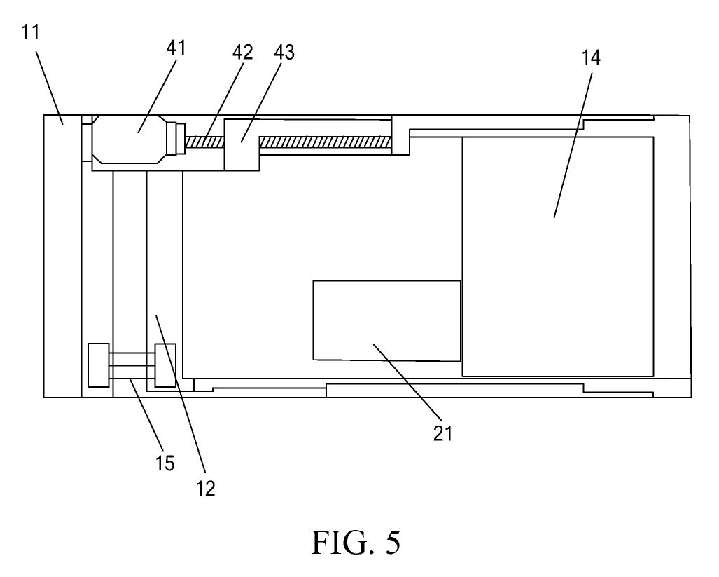

The communication device includes a case. When the main circuit board 12 is moved to the use position, the antenna 14 is just exposed out of the case of the communication device, thus meeting the use requirements of the antenna. When the main circuit board 12 moves to the accommodation position, the antenna 14 is completely accommodated into the case of the communication device, thus being convenient for the storage and transportation of the communication device. FIG. 5 is a schematic structural view of a communication device in an accommodation state according to the second embodiment of this invention.

The main circuit board 12 is provided with a SIM socket 21, which moves with the main circuit board 12. When the main circuit board 12 is at the accommodation position, a load/unload opening of the SIM socket 21 is accommodated into the communication device with the main circuit board 12, thus forming good sealing protection on the SIM card and the SIM socket 21. When the main circuit board 12 is at the use position, the load/unload opening of the SIM socket 21 is exposed for loading/unloading the SIM card.

The power supply of the SIM card is turned off when no SIM card inserted is detected. The SIM card is powered on only when it is detected that a SIM card is inserted into the SIM socket 21, thus avoiding hot plug of the SIM card.

Referring to FIGS. 4 and 5, in the embodiment of this invention, the main circuit board 12 and the interface circuit board 11 are connected through the flexible wire 15. The interface circuit board 11 is provided with a drive motor 41. A screw 42 is provided between the interface circuit board 11 and the main circuit board 12, an end of the screw 42 is connected to the interface circuit board 11, and the other end is fixed on the main circuit board 12 through a nut. When the drive motor 41 is launched, the drive motor 41 drives the screw 42 to move, so as to impel the nut 43 on the screw 42 to move in a parallel manner, thus the nut 43 on the screw 42 drives the main circuit board 12 to move. At the same time, the screw 42 serves as a guide rail and limits the main circuit board 12 to move along the screw 42 in a parallel direction in the length rage of the screw 42. The movement direction of the main circuit board 12 can be changed by changing the rotation direction of the screw 42. When the main circuit board 12 moves to the use position, the antenna 14 is located out of the communication device, thus meeting the use requirements of the antenna 14. At this time, the communication device transmits/receives radio-frequency signals through the antenna 14, so as to perform data communication.

When the main circuit board 12 is moved through motor driving to make main circuit board 12 located at the accommodation position, the antenna 14 is completely accommodated into the communication device with the movement of the main circuit board 12, and is not exposed out of the communication device, thus being convenient for the storage and transportation of the communication device.

According to an embodiment of this invention, a communication device is provided, in which the antenna and the main circuit board are fixedly connected, and the main circuit board adopts a retractable structure. When the main circuit board moves to the use position, the antenna is just exposed out of the case of the communication device, so that the antenna can transmit/receive radio-frequency signals, thus meeting the use requirements of the antenna. When the main circuit board moves to the accommodation position, the antenna is accommodated into the case of the communication device, thus being convenient for the storage and transportation of the communication device. Further, the communication device has simple design, can be realized easily, and is beneficial to improving the automatization of the communication device.

Those of ordinary skill in the art can understand that the drawings are merely schematic views of a preferred embodiment, and modules in the drawings are not necessarily required for implementation of this invention.

The solutions in the claims are also in the protection scope of this invention.

Those of ordinary skill in the art can understand that the modules in the device in the embodiment can be distributed in the device of the embodiment according to the description of the embodiment, and can also be changed correspondingly and located in one device or a plurality of devices different from the embodiment. The modules of the embodiment can be integrated into one module, and can be further divided into a plurality of sub-modules.

Herein, merely some specific embodiments of this invention are disclosed, but this invention is not limited thereto. Any variations made by those of ordinary skill in the art shall fall in the protection scope of this invention.

1. A communication device, having a peripheral component interconnection, PCI, Express interface, comprising:
an interface circuit board, configured to bear the PCI Express interface;
a main circuit board, connected to the interface circuit board through soft link, and configured to process first data and transmit the first data to the PCI Express interface, and receive second data from the PCI Express interface and process the second data;
a guide rail, configured to bear the main circuit board, so that the main circuit board slides between a use position and an accommodation position through the guide rail; and
an antenna, installed on the main circuit board, and located at different positions with the movement of the main circuit board.

2. The communication device according to claim 1, wherein the use position of the main circuit board is corresponding to a use state of the main circuit board, and the accommodation position of the main circuit board is corresponding to an accommodation state of the main circuit board.

3. The communication device according to claim 1, further comprising a case, wherein
when the main circuit board moves to the user position, the antenna is exposed out of the case; and
when the main circuit board moves to the accommodation position, the antenna is completely accommodated into the case.

4. The communication device according to claim 1, wherein the main circuit board and the interface circuit board are in the same plane.

5. The communication device according to claim 1, further comprising
a drive motor, fixedly connected to the interface circuit board;
a screw, with an end connected to the drive motor, driven by the drive motor to rotate; and
a nut, fixed on the main circuit board, with a thread matching with a thread of the screw, wherein the screw is fitted in the nut.

6. The communication device according to claim 5, wherein the interface circuit board includes a drive circuit of the drive motor, and the drive circuit obtains a drive current from the PCI Express interface.

7. The communication device according to claim 1, further comprising:
a subscriber identity module, SIM, socket, disposed on the main circuit board, moving with the movement of the main circuit board, wherein when the main circuit board is at the accommodation position, a load/unload opening of the SIM socket is in the communication device, and when the main circuit board is at the use position, the load/unload opening of the SIM socket is exposed.

8. The communication device according to claim 7, wherein the main circuit board comprises a SIM power detection circuit, configured to power off a SIM card when detecting no SIM card in the SIM socket and power on the SIM card when detecting a SIM card installed into the SIM socket.

9. The communication device according to claim 1, further comprising:
a flexible wire, connected to the main circuit board by one end and connected to the interface circuit board by the other end.

10. The communication device according to claim 1, further comprising:
a flexible printed circuit board, configured to electrically connect the main circuit board to the interface circuit board.
